(19) United States
(12) Patent Application Publication
(10) Pub. No.: US 2009/0166319 A1
(43) Pub. Date: Jul. 2, 2009

(54) System and Method for Performing High Flow Rate Dispensation of a Chemical onto a Photolithographic Component

(76) Inventors: Daniel Courboin, Corbeil Essonnnes (FR); Jong Woo Choi, KyungGi (KR)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 12/374,039

(22) PCT Filed: Jul. 19, 2007
(86) PCT No.: PCT/US07/73881

§ 371 Date: Jan. 15, 2009

Related U.S. Application Data
(60) Provisional application No. 60/807,903, filed on Jul. 20, 2006.

(51) Int. Cl. B44C 1/22; G03F 7/26

(52) U.S. Cl. 216/13; 430/494; 118/323; 156/345.21; 216/23

(57) ABSTRACT

A system and method for performing high flow rate dispensation of a chemical onto a photolithographic component are disclosed. The system and method includes providing a photolithographic component in a manufacturing tool. The photolithographic is positioned at a predetermined distance from a nozzle dispensing a chemical. Dispensation of a chemical at a high flow rate onto a photolithographic component, the rate of flow operable to reduce harmful effects from occurring on the surface of the photolithographic substrate.

### CROSS-REFERENCE TO RELATED APPLICATIONS

This application is a U.S. national stage application of International Application No. PCT/US2007/073881 filed Jul. 19, 2007, which designates the United States of America, and claims the benefit of U.S. Provisional Application No. 60/807,903 filed on Jul. 20, 2006, the contents of which are incorporated herein by reference in their entirety.

### TECHNICAL FIELD

This disclosure relates in general to semiconductor manufacturing and, more particularly, to a system and method for high flow rate dispensation of a chemical onto a photolithographic component

### BACKGROUND OF THE DISCLOSURE

Photolithographic components are integral to the design and fabrication of integrated circuits (ICs), liquid crystal displays (LCDs), flat panel displays, color filters, compact disks, digital video disks (DVDs), and numerous other electronic devices (as used herein, the phrase “electronic devices” means ICs, color filters, LCDs, flat panel displays, compact disks, DVDs, and all other devices suitable for manufacturing using photolithography). For example, ICs fabricated using photolithographic components include, without limitation, microchips, microcontrollers, memory chips, and application specific integrated circuits (ASICs). Photolithographic components may include, without limitation, photomasks, semiconductor wafers, thin film transistor array substrates (e.g. for use in the manufacture of LCDs, flat panel displays and color filters), glass masters (e.g., for use in the manufacture of compact disks and DVDs), or any other suitable substrate which can be processed using photolithography.

Advances in the design of electronic devices and the manufacturing techniques used to create such electronic devices have contributed to the reduction in size of design features used to form electronic devices. As feature sizes shrink, the number of features that may be used to form an electronic device, and the densities of structures included on photolithographic components increase. With the increased densities and smaller feature sizes, manufacturers have placed greater emphasis on ensuring that critical dimensions (CD) of features remain consistent across photolithographic components. CD is one of the most critical parameters in industries using photolithography to manufacture electronic devices. If measures are not taken to ensure adequate uniformity of CD across a photolithographic component, ICs manufactured with such components may prove faulty or defective.

During manufacture of a photolithographic component, particularly during the development, etch and deposition steps, by-products from the materials used to both develop and etch the layers of the photolithographic component may be produced. These by-products may create harmful effects known as microloading effects that can cause problems with CD uniformity across the component.

Various techniques have been used to minimize loading effects caused by -products produced during the develop and etch processes. For example, one conventional technique uses a nozzle having inlets that suction extra developer or etch solution from the surface of a substrate and outlets that simultaneously supply the solution to the surface of the substrate. Development is performed by scanning the nozzle from one side of the substrate to the other side. This technique requires that the flow rate of the developer and rinse stay identical, which may increase the rate of pattern collapse. Additionally, the technique requires use of a large amount of chemicals (both the developer and the rinse) and requires a develop time that depends on the scanning speed of the nozzle.

Another conventional technique involves maintaining a liquid agent between a substrate and a holding structure that functions to hold the liquid close to the substrate. The holding structure and/or the substrate are moved horizontally while the surface of the substrate is being treated with the liquid agent, which causes the concentration of reaction products and reaction materials to become uniform. This technique, however, does not provide for the removal of used liquid agent, which does not prevent microloading effects from occurring. Additionally, a rinse solution must be applied from a separate nozzle, which increases develop time.

### SUMMARY OF THE DISCLOSURE

In accordance with the present disclosure, the disadvantages and problems associated with the manufacture of a photolithographic component have been reduced or eliminated. In a particular embodiment, a chemical may be dispensed by a nozzle onto a photolithographic component in order to reduce harmful effects occurring on the surface of the component.

In accordance with one embodiment of the present disclosure, a method for dispensation of a chemical onto a photolithographic component includes providing a photolithographic component in a manufacturing tool, and positioning the component at a predetermined distance from a nozzle. The nozzle dispenses a chemical on the surface of the photolithographic component at a high flow rate such that the rate of flow may reduce harmful effects occurring on the surface of the component.

In accordance with another embodiment of the present disclosure, an apparatus for dispensation of a chemical onto a photolithographic component includes a nozzle operable to dispense the chemical at a high flow rate on the surface of the photolithographic component such that the rate of flow may reduce the occurrence of harmful effects on the surface of the component. The apparatus also includes a substrate holder operable to position the photolithographic component at a predetermined distance from the nozzle.

In accordance with an additional embodiment of the present disclosure, a method for performing high flow rate development of a photolithographic component includes providing a photolithographic component in a manufacturing tool, the photolithographic component including a resist layer having a pattern imaged therein. The photolithographic component is positioned at a predetermined distance from a nozzle operable to dispense a developer solution. The developer solution is dispensed on the surface of the resist layer at a high flow rate such that the rate of flow may ensure uniform development of the pattern across the surface of the component.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a cross-sectional view of photomask assembly according to teachings of the present disclosure;

FIG. 2 illustrates a photolithography system that images a pattern created by patterned layer and clear areas on photomask on to the surface of photolithographic component, according to teachings of the present disclosure;

FIGS. 3A-3E illustrate an example photomask with portions broken away showing cross-sectional side views at various stages of manufacture according to teachings of the present disclosure;

FIG. 4 illustrates an example method for fabricating a photomask according to teachings of the present disclosure;

FIG. 5 illustrates an apparatus for performing high flow rate dispensation of a chemical onto a photolithographic component during manufacturing of the photolithographic component according to teachings of the present disclosure; and

FIG. 6 illustrates a flow chart of a method for performing high flow rate dispensation of a chemical onto a photolithographic component during manufacturing of the photolithographic component according to teachings of the present disclosure.

### DETAILED DESCRIPTION OF THE DISCLOSURE

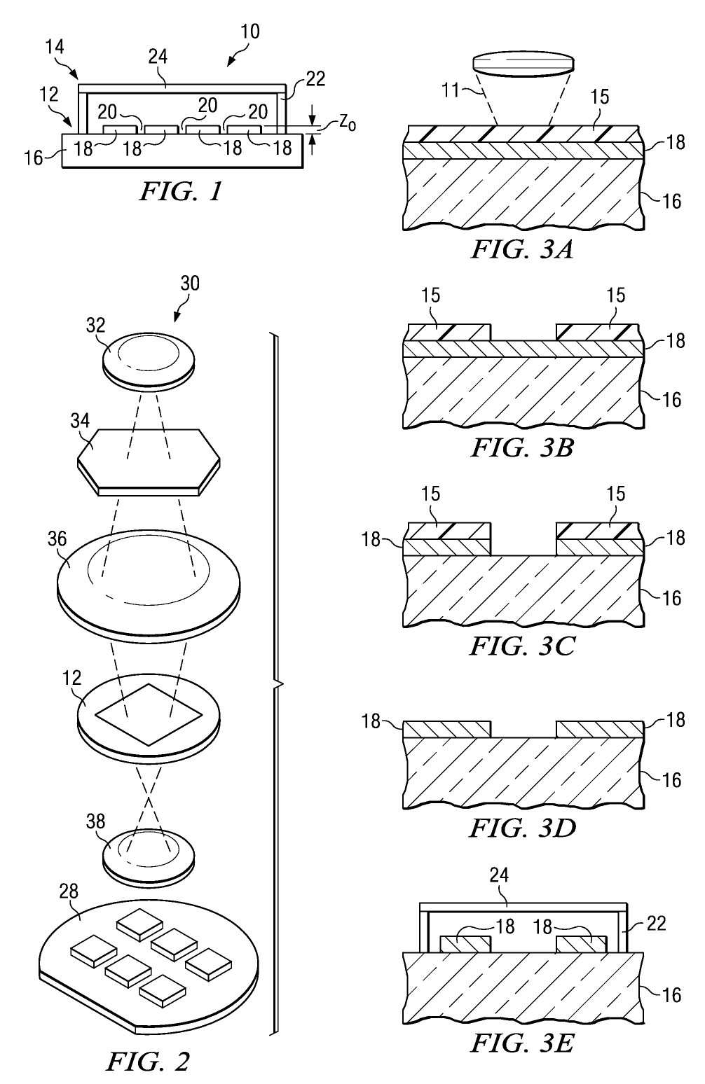

Preferred embodiments of the present disclosure and their advantages are best understood by reference to FIGS. 1 through 6, where like numbers are used to indicate like and corresponding parts.

FIG. 1 illustrates a cross-sectional view of photomask assembly 10. Photomask assembly 10 includes photomask 12 coupled to pellicle assembly 14. Substrate 16 and patterned layer 18 form photomask 12, otherwise known as a mask or reticle, that may have a variety of sizes and shapes, including but not limited to round, rectangular, or square. Photomask 12 may also be any variety of photomask types, including, but not limited to, a one-time master, a five-inch reticle, a six-inch reticle, a nine-inch reticle or any other appropriately sized reticle that may be used to project an image of a circuit pattern onto a semiconductor wafer. Photomask 12 may further be a binary mask, a phase shift mask (PSM), an optical proximity correction (OPC) mask or any other type of mask suitable for use in a lithography system. In other embodiments, photomask 12 may be a step and flash imprint lithography (SFIL) mask that does not include pellicle assembly 14.

Photomask 12 includes patterned layer 18 formed on substrate 16 that, when exposed to electromagnetic energy in a lithography system, projects a pattern onto a surface of a semiconductor wafer (not expressly shown). Substrate 16 may be a transparent material such as quartz, synthetic quartz, fused silica, magnesium fluoride (MgF₂), calcium fluoride (CaF₂), or any other suitable material that transmits at least seventy-five percent (75%) of incident light having a wavelength between approximately 10 nanometers (nm) and approximately 450 nm. In an alternative embodiment, substrate 16 may be a reflective material such as silicon or any other suitable material that reflects greater than approximately fifty percent (50%) of incident light having a wavelength between approximately 10 nm and 450 nm.

Patterned layer 18 may be a metal material such as chrome, chromium nitride, a metallic oxy-carbo-nitride (e.g., MOCN, where M is selected from the group consisting of chromium, cobalt, iron, zinc, molybdenum, niobium, tantalum, titanium, tungsten, aluminum, magnesium, and silicon), or any other suitable material that absorbs electromagnetic energy with wavelengths in the ultraviolet (UV) range, deep ultraviolet (DUV) range, vacuum ultraviolet (VUV) range and extreme ultraviolet range (EUV). In an alternative embodiment, patterned layer 18 may be a partially transmissive material, such as molybdenum silicide (MoSi), which has a transmissivity of approximately one percent (1%) to approximately thirty percent (30%) in the UV, DUV, VUV and EUV ranges. In a further embodiment, patterned layer 18 may be created by etching a pattern directly into substrate 16.

Frame 20 and pellicle film 22 may form pellicle assembly 14. Frame 20 is typically formed of anodized aluminum, although it could alternatively be formed of stainless steel, plastic or other suitable materials that do not degrade or outgas when exposed to electromagnetic energy within a lithography system. Pellicle film 22 may be a thin film membrane formed of a material such as nitrocellulose, cellulose acetate, an amorphous fluoropolymer, such as TEFLON® AF manufactured by E. I. du Pont de Nemours and Company or CYTOP® manufactured by Asahi Glass, or another suitable film that is transparent to wavelengths in the UV, DUV, EUV and/or VUV ranges. Pellicle film 22 may be prepared by a conventional technique such as spin casting.

Pellicle film 22 protects photomask 12 from contaminants, such as dust particles, by ensuring that the contaminants remain a defined distance away from photomask 12. This may be especially important in a lithography system. During a lithography process, photomask assembly 10 is exposed to electromagnetic energy produced by a radiant energy source within the lithography system. The electromagnetic energy may include light of various wavelengths, such as wavelengths approximately between the I-line and G-line of a Mercury arc lamp, or DUV, VUV or EUV light. In operation, pellicle film 22 is designed to allow a large percentage of the electromagnetic energy to pass through it. Contaminants collected on pellicle film 22 will likely be out of focus at the surface of the wafer being processed and, therefore, the exposed image on the wafer should be clear. Pellicle film 22 formed in accordance with the teachings of the present invention may be satisfactorily used with all types of electromagnetic energy and is not limited to lightwaves as described in this application.

Photomask 12 may be formed from a photomask blank using a standard lithography process. In a lithography process, a mask data file that includes data for patterned layer 18 may be generated from a mask layout file. The mask layout file may include polygons that represent transistors and electrical connections for an integrated circuit. The polygons in the mask layout file may further represent different layers of the integrated circuit when it is fabricated on a semiconductor wafer. For example, a transistor may be formed on a semiconductor wafer with a diffusion layer and a polysilicon layer. The mask layout file, therefore, may include one or more polygons drawn on the diffusion layer and one or more polygons drawn on the polysilicon layer. The polygons for each layer may be converted into a mask data file that represents one layer of the integrated circuit. Each mask data file may be used to generate a photomask for the specific layer.

In accordance with the present disclosure, the systems and methods disclosed herein reduce harmful effects, such as microloading, that occur during the development and etching steps of a photomask manufacturing process. Similarly, the systems and methods disclosed herein reduce harmful effects, such as microloading, that occur during the development, etching and layer growth steps of manufacturing electronic devices. For example, in accordance with the present disclosure, a developer solution used in the manufacture of a photomask, silicon wafer, or other photolithographic substrate may be dispensed onto the substrate at a high flow rate, which has been found to reduce harmful effects, including microloading, that occur during the development, etching, and layer growth steps in the manufacture of electronic devices.

FIG. 2 illustrates a photolithography system that images a pattern created by patterned layer 18 and clear areas 20 on photomask 12 on to the surface of photolithographic component 28. Photolithography system 30 includes light source 32, filter 34, condenser lens 36 and reduction lens 38. In one embodiment, light source 32 may be a mercury vapor lamp that emits wavelengths between approximately 350 nm and 450 nm. In another embodiment, light source 32 may be an argon-ion laser that emits a wavelength of approximately 364 nm. In other embodiments, light source 32 may emit wavelengths between approximately 150 nm and approximately 350 nm. Filter 34 selects the wavelength to be used in photolithography system 30 and condenser lens 36 and reduction lens 38 use refractive optics to focus the radiant energy from light source 32 respectively onto photomask 12 and photolithographic component 28.

During a photolithography process, electromagnetic energy illuminates photomask 12 and an image of the pattern on photomask 12 is projected onto photolithographic component 28. The pattern on photomask 12 is reduced by reduction lens 38 such that the image is only projected on a portion of photolithographic component 28. Photolithography system 30 then realigns photolithographic component 28 so that the pattern from photomask 12 may be imaged onto another portion of photolithographic component 28. The process is repeated until all or most of the surface of photolithographic component 28 is covered by multiple instances of the pattern from photomask 12.

An electronic device manufacturer may use photomask 12 to fabricate substrates using the selected etch process without having to manually adjust the etch process. For example, photomask 12 may be placed in photolithography system 30 to image a pattern onto a resist layer formed on photolithographic component 28. The areas of the resist layer that are exposed to the electromagnetic energy are then developed and etched to expose corresponding regions of a conductive material, such as polysilicon or metal. The conductive material is etched and the remaining resist is removed. If the conductive material is not the last layer to be formed on photolithographic component 28, an insulating layer is formed on the conductive layer and an additional conductive layer and resist layer are formed on the insulating layer. The photolithography, developing, etching and depositing steps are repeated until all layers of the semiconductor device have been formed.

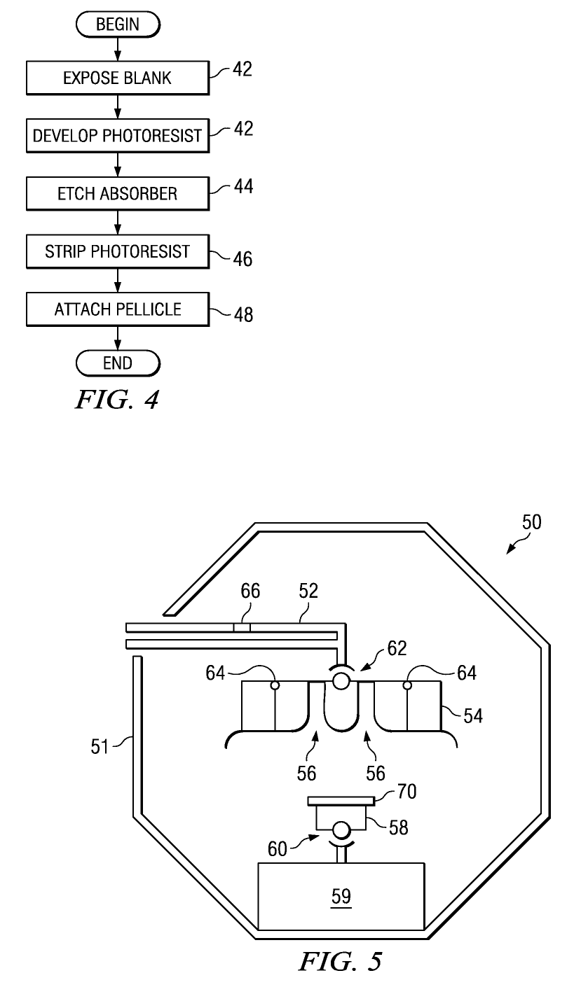

FIGS. 3A-3E illustrate an example photomask with portions broken away showing cross-sectional side views at various stages of manufacturing a photomask. FIG. 4 illustrates an example method for fabricating photomask according to the invention.

Referring now to block 40 of FIG. 4, the example process may begin with the photomask manufacturer exposing a pattern onto a photomask blank. As illustrated in FIG. 3A, the photomask blank may include a transparent substrate 16, absorber layer 18 that coats at least a portion of a surface of transparent substrate 16, and a layer of photoresist 15 that coats at least a portion of absorber layer 18. The photomask manufacturer may expose the pattern in photoresist 15 using electromagnetic radiation 11. Electromagnetic radiation 11 may be an electron beam, a laser beam, X-ray photolithography tool, or any other suitable source of electromagnetic radiation.

As depicted in FIG. 3B and block 42 of FIG. 4, photoresist 15 may be developed, which causes portions of photoresist 15 to be removed according to the pattern exposed in the previous step. In one embodiment, at block 42 a chemical such as a photoresist developer may be dispensed onto photomask 12 (or other photolithographic component) in a manufacturing tool, with photomask 12 (or other photolithographic component) positioned at a predetermined distance from a nozzle. In another embodiment, the nozzle may dispense the etching agent or chemical on the surface of photomask 12 (or other photolithographic component) at a high flow rate, where the rate of flow may reduce harmful effects, such as microloading, occurring on the surface of the component. In the example embodiment of FIGS. 3A-3E a positive resist process is used, in which a developer dissolves the areas of photoresist 15 that have been exposed, to uncover regions of absorber layer 18 formed on transparent substrate 16. However, a negative photoresist may be used in alternative embodiments. As shown in FIG. 3B and block 44 of FIG. 4, the manufacturer may etch away absorber layer 18 in the areas that have been cleared of photoresist 15 to expose areas of transparent substrate 16.

After selected portions of absorber layer 18 are etched, photoresist 15 may stripped from the patterned blank, as shown in FIG. 3D and in block 46 of FIG. 4. At this point, photomask 12 may be referred to as a “patterned substrate.” Also, the process of etching absorber layer 18 and substrate 16, may be referred to as “patterning” the mask. In one embodiment, at block 46 a chemical such as an etching agent may be dispensed onto photomask 12 (or other photolithographic component) in a manufacturing tool, with photomask 12 (or other photolithographic component) positioned at a predetermined distance from a nozzle. In another embodiment, the nozzle may dispense the etching agent or chemical on the surface of photomask 12 (or other photolithographic component) at a high flow rate, where the rate of flow may reduce harmful effects, such as microloading, occurring on the surface of the component.

In addition, as shown in FIG. 3E and block 48 of FIG. 4, the manufacturer may attach a pellicle to the photomask before shipping the photomask to the customer. The pellicle may include a pellicle film 22 that is suspended a certain distance above substrate 16 by pellicle frame 20, so that if any dirt (e.g., dust particles) sticks to pellicle membrane 22, those particles will be out of focus with respect to the image that the photomask produces on an object substrate when the photomask is transilluminated. Pellicle membrane 22 may also provide additional protection against pattern damage.

Although FIGS. 3A-3E and 4 set forth a series of steps that may be utilized to manufacture a photomask, it is understood that a photomask may be manufactured without utilizing one or more of the steps described above or with utilizing one or more steps not described above. For example, one may use techniques known in the art to add additional layers or structures on photomask 12, including without limitation, antireflective layers, antireflective coatings, and protective coatings. Furthermore, one skilled in the art to which the present invention pertains will appreciate that ICs and other electronic devices may be fabricated in a manner analogous to (but not necessarily identical to) the method depicted above.

Furthermore, although FIGS. 2-4 depict a particular process for manufacturing a photomask or other photolithographic component, it is understood that any and all suitable methods for manufacturing a photolithographic component may be used. For example, the development, etching and layer growth steps used may be any suitable method for developing, etching and promoting layer growth on a substrate, including without limitation any development, etch, deposition or growth process performed using a solvent or water-based chemical to promote development, etching, deposition and/or layer growth.

FIG. 5 illustrates an embodiment of an apparatus 50 for high flow rate dispensation of a chemical onto a photolithographic component 70 during manufacturing of photolithographic component 70, according to the present invention. Photolithographic component 70 may be a photomask blank, semiconductor wafer, thin film transistor array substrate, glass master, or other substrate capable of being fabricated using photolithography. In the illustrated embodiment, apparatus 50 includes process chamber 51, arm 52, nozzle 54, substrate holder 58 and substrate holder arm 59. Process chamber 51 may be any suitable process chamber known in the art for processing photolithographic components.

In the depicted embodiment, arm 52 is coupled to nozzle 54 at point 62 and is capable of moving nozzle 54 in a substantially horizontal direction within process chamber 51. In one embodiment, nozzle 54 is rotatably coupled to arm 52 at point 62, allowing nozzle 54 to rotate at a plurality of speeds. In another embodiment, nozzle 54 is fixed in a stationary manner to arm 52. In an additional embodiment, nozzle 54 may be mounted to arm 52 at point 62 using a “kneecap” system in order to allow finer movements of nozzle 54 relative to the other elements of apparatus 50.

Nozzle 54 may include one or more holes 56 operable to dispense chemicals, such as photoresist developer, etching agent or de-ionized water, within process chamber 51. Holes 56 may be connected to one or more conduits (not shown) capable of transporting chemicals to holes 56 from a location exterior to process chamber 51. Furthermore, although FIG. 5 depicts two holes 56, it is understood that nozzle 54 may include any number of holes 56.

Substrate holder arm 59 is coupled to substrate holder 58 at point 60 and is capable of moving substrate holder 58 in a substantially vertical direction within process chamber 51. In one embodiment, one or more photolithographic components 70, are disposed on substrate holder 58 during the chemical disbursement method disclosed herein. In an additional embodiment, substrate holder 58 is rotatably coupled to substrate holder arm 59 at point 60, allowing substrate holder 58 to rotate at a plurality of speeds. In another embodiment, substrate holder is fixed in a stationary manner to substrate holder arm 59. In another embodiment, substrate holder 58 may be mounted to substrate holder arm 59 at point 60 using a “kneecap” system in order to allow finer movements of substrate holder 58 relative to the other elements of apparatus 50 including nozzle 54. Although only one photolithographic component 70 is depicted in FIG. 5, it is understood that any number of photolithographic components may be disposed on substrate holder 58.

Apparatus 50 may also include one or more distance sensors 64 for determining a distance between nozzle 54 and the surface of photolithographic component 70. Distance sensors 64 may include any suitable device for detecting proximity between two objects, such as a photodiode sensor. Although distance sensors 64 are depicted as being coupled to nozzle 54, it is understood that distance sensors 64 may be disposed at any suitable location within apparatus 50. Furthermore, although two distance sensors 64 are depicted in FIG. 5, it is understood that apparatus 50 may include any number of distance sensors 64.

Apparatus 50 may further include one or more pressure sensors 66 for determining the pressure applied by a chemical dispensed by the nozzle onto the resist layer. Pressure sensors 66 may include any suitable device for determining the pressure applied to an object. Although pressure sensor 66 is depicted as being coupled to arm 52, it is understood that the pressure sensor 66 may be disposed at any suitable location within apparatus 50. Although apparatus 50 depicts one pressure sensor 66, it is understood that apparatus 50 may comprise any number of pressure sensors 66.

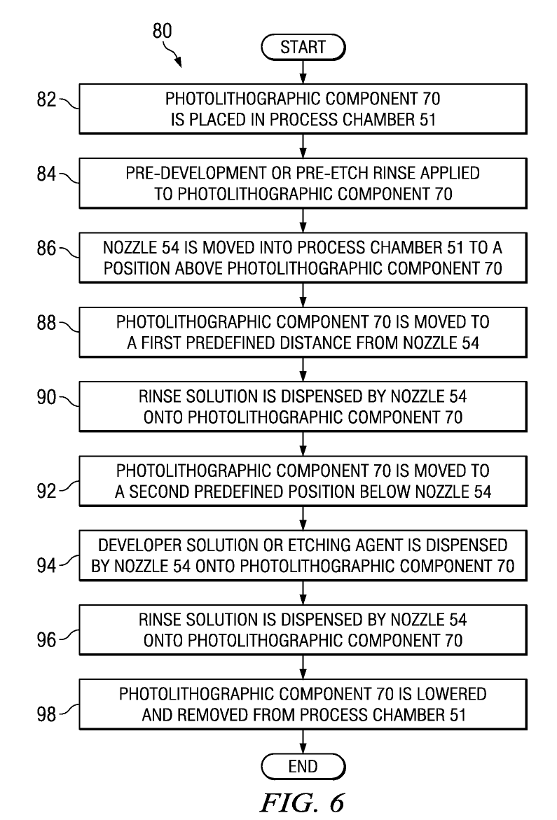

FIG. 6 illustrates a flow chart of a method 80 for high flow rate dispensation of a chemical onto a photolithographic component 70 during manufacturing the photolithographic component 70. Such dispensation of chemicals may be performed in order to assist in etching, layer growth, developing or cleaning a photolithographic component. For example, in some embodiments, method 80 may be utilized to perform a development step similar to development block 42 of the method depicted in FIG. 4, in which case photolithographic component 70 may include a layer of photoresist on the surface of the photolithographic component. In another embodiment, method 80 may be utilized to perform an etching step similar to etching step 44 of the method depicted in FIG. 4.

In one embodiment, method 80 includes placing nozzle 54 and photolithographic component 70 in proximity to each other within process chamber 51. While in proximity to photolithographic component 70, nozzle 54 may dispense one or more chemicals, such as photoresist developer, etching agent or de-ionized water, onto the substrate at a high flow rate. Once the desired chemicals have been applied to photolithographic component 70, photolithographic component 70 may be removed from process chamber 51 for further processing.

According to one embodiment, method 80 may begin at step 82. As mentioned above, teachings of the present disclosure may be implemented using a variety of photolithography techniques which may be similar to the method described in FIG. 4, but not necessarily identical to method described in FIG. 4. As such, the starting point for method 80, the order of the steps 82-98 comprising method 80, and whether one or more of steps 82-98 comprising method 80 are utilized, or whether steps in addition to steps 82-98 are utilized, may depend on the method of photolithography chosen, as well as the particular photolithographic component being manufactured.

At step 82, photolithographic component is placed in process chamber 51, preferably by being transported upon substrate holder 58 in a substantially vertical direction. In some embodiments, at step 84, a pre-development, pre-etching or pre-growth rinse, or other rinse solution, such as de-ionized water, may be dispensed on photolithographic component 70 by nozzle 54 or another element of apparatus 50. Such dispensation of chemicals may be desirable in some photolithographic techniques, for example, to clean contaminants from the surface of photolithographic component 70 or in those techniques in which it is desirable to maintain a thin layer of a desired chemical on photolithographic component during etch, development, layer growth or cleaning.

At step 86, nozzle 54 is moved into process chamber 51 to a position in proximity to photolithographic component 70. In one embodiment, nozzle 54 is moved in a substantially horizontal direction to its desired location within process chamber 51 by arm 52.

At step 88, photolithographic component 70 may be moved to a first predefined distance below nozzle 54. The first predefined position may be determined by the user in order to optimize the results of the photolithography process and may be based on a number of factors, including the photolithography technique being practiced, the flow rate of the chemical dispensed at step 90 (see below) or the chemical properties of the such chemical, photolithographic component 70 or any resist or other substance disposed upon photolithographic component 70.

At step 90, another rinse solution, such as de ionized water, may be dispensed by nozzle 54 through one or more holes 56 onto photolithographic component 70. Such rinse solution may or may not be the same as the rinse dispensed in step 84. Such dispensation of chemical may be desirable in some photolithographic techniques, for example, to clean contaminants from the surface of photolithographic component 70 or in those techniques in which it is desirable to maintain a thin layer of a desired chemical on photolithographic component during etch, development, layer growth or cleaning.

At step 92, photolithographic component 70 may be moved to a second pre-determined position below nozzle 54. The second predefined position may be determined by the user to optimize the photolithography process and may be based on a number of factors, including the photolithographic technique being practiced, the flow rate of the chemical dispensed at steps 94 or 96 (see below) or the chemical properties of the such chemical, photolithographic component 70 or any resist or other substance disposed upon photolithographic component 70. At step 94, a developer solution for removing developed photoresist from photolithographic component 70, an etching agent for use in etching photolithographic component 70 or any other suitable chemical may be dispensed by nozzle 54 through one or more holes 56 onto photolithographic component 70. The one or more holes 56 through which such chemical is dispensed may be the same or different holes 56 than through which the rinse solutions are dispensed in steps 84 and 90.

At step 96, a rinse solution, such as de-ionized water, may be dispensed by nozzle 54 through one or more holes 56 onto photolithographic component 70. The one or more holes 56 through which such rinse solution is dispensed may be the same or different holes 56 than through which other chemicals are dispensed in other steps of method 80. Furthermore, such rinse solution may or may not be the same as the rinse solutions dispensed in steps 84 and 90. In one embodiment, in which method 80 is being used to develop photolithographic component 70, the rinse solution may comprise a rinse, such as de-ionized water, for removing any excess developer dispensed in step 94 or any reaction by-products of the developer and the developed photoresist which remains on the surface of photolithographic component 70. At step 98, photolithographic component 70 may be removed from process chamber 51 and be further processed by the photolithographic component manufacturer.

In steps 88, 90, 92, 94 and 96 of method 80, the distance between nozzle 54 and photolithographic component 70 may be monitored and controlled by numerous means. In one embodiment, one or more distance sensors 64, such as a photodiode sensor, may be utilized to determine the distance between nozzle 54 and photolithographic component 70. In another embodiment, distance may be monitored by one or more pressure sensors 66. In yet another embodiment, the distance may be controlled by moving substrate holder 58 upon which photolithographic component 70 rests in a substantially vertical manner within process chamber 51. In another embodiment, the distance may be controlled by varying the chemical flow rate of the chemical being dispensed from nozzle 54. The desired distances between nozzle 54 and photolithographic component 70 at steps 88, 90, 92, 94 and 96 may be based on numerous factors, including the photolithographic technique being practiced, the flow rate of the respective chemicals dispensed, the chemical properties of the respective chemicals, the chemical properties of photolithographic component 70 or any resist or other substance disposed upon photolithographic component 70, or the reaction rates of reactions between the respective chemicals and features on photolithographic component 70. In some embodiments, the distance between nozzle 54 and photolithographic component 70 may be between approximately 10 microns and approximately 1000 microns. In other embodiments, the distance between nozzle 54 and photolithographic component 70 may be varied during dispensation of chemicals at steps 90, 94 and 96, so as to reduce the risk of pattern collapse or other harmful effects that may damage features on photolithographic component 70.

In certain embodiments, it may be desirable to monitor and control the pressure placed on photolithographic component 70 by a chemical dispensed by nozzle 54. The pressure may be monitored by one or pressure sensors 66 and may be controlled by varying the flow rates of the respective chemicals being dispensed or varying the distance between nozzle 54 and photolithographic component 70. In some embodiments, the pressure, distance and or a combination of both may be varied to reduce the risk of pattern collapse or other harmful effects that may damage features on photolithographic component 70.

Although method 80 describes that particular chemicals may be dispensed during steps 94, 90, 94 and 96, chemicals dispensed during such steps may be any suitable chemical that can be utilized to facilitate development, etching, layer growth or cleaning of a photolithographic component.

In a particular embodiment of method 80, photolithographic component 70 may be rotated at a desired speed during one of more steps comprising method 80. For example, photolithographic component 70 may be rotated significantly contemporaneous to the chemicals being dispensed upon photolithographic component 70 at steps 84, 90, 94 and 96 of method 80. Such rotation may be utilized to, among other things, ensure a uniform distribution of dispensed chemicals over the surface of photolithographic component 70 and ensure that dispensed chemicals drain from the edges of photolithographic component 70. In preferred embodiments, photolithographic component 70 may be rotated between 1 rpm and 3000 rpm. Rotation of photolithographic component 70 may be facilitated by the rotation of substrate holder 58 or substrate holder arm 59.

In a particular embodiment of method 80, nozzle 54 may be rotated at a desired speed during one of more steps comprising method 80. For example, nozzle 54 may be rotated significantly contemporaneous to the chemicals being dispensed upon photolithographic component 70 at steps 84, 90, 94 and 96 of method 80. Such rotation may be utilized to, among other things, ensure a uniform distribution of dispensed chemicals over the surface of photolithographic component 70. In preferred embodiments, nozzle 54 may be rotated between 1 rpm and 3000 rpm. Rotation of nozzle 54 may be facilitated by the rotation of nozzle 54 about point 62. In addition, nozzle 54 and photolithographic component 70 may rotate at the same or different speeds or at the same or different center of rotation.

In a particular embodiment of method 80, the chemicals dispensed at steps 84, 90, 94 and 96 of method 80 may be dispensed at a variety of flow rates. The desired flow rates of the respective chemicals may be based on numerous factors, including the photolithographic technique being practiced, the distance between nozzle 54 and photolithographic component 70, the chemical properties of the respective chemicals, the chemical properties of photolithographic component 70 or any resist or other substance disposed upon photolithographic component 70, or reaction rates of reactions between the respective chemicals and features on photolithographic component 70. In preferred embodiments, the respective chemicals may be dispensed at a rate between approximately 0.1 l/min and approximately 10 l/min.

In another particular embodiment of apparatus 50 and method 80, a pad (not shown), much like that used in chemical mechanical polishing (CMP), may be disposed between nozzle 54 and photolithographic component 70 to further facilitate development, etching, layer growth and/or cleaning of a photolithographic component.

In another particular embodiment of method 80, the chemicals dispensed at steps 84, 90, 94 and 96 of method 80 may be dispensed at a substantially uniform temperature. The desired uniform temperature may be based on numerous factors, including the photolithographic technique being practiced, photolithographic component 70, the chemical properties of the respective chemicals, the chemical properties of photolithographic component 70 or any resist or other substance disposed upon photolithographic component 70, or reaction rates of reactions between the respective chemicals and features on photolithographic component 70. In some embodiments, the desired uniform temperature may be at a temperature between approximately 15°-25° C.

In another particular embodiment, the desired uniform temperature of method 80 may be maintained such that the temperature gradient across the surface of photolithographic component 70 does not exceed approximately 0.2° C.

Although apparatus 50 depicts one photolithographic component 70, it is understood that method 80 may be utilized to perform steps 82-98 on any number of photolithographic components simultaneously.

The advantages of the methods and systems disclosed herein are numerous. For example, by using a high flow rate (e.g., between approximately 0.1 l/min and approximately 10 l/min) of a chemical, such as a developer chemical or etching agent, in close proximity (e.g., between approximately 10 microns to 1000 microns) to a photolithographic component, reaction by-products which lead to microloading effects are quickly and efficiently removed near the surface of the photolithographic component and replaced with “fresh” developer or etching agent. Furthermore, the present disclosure contemplates that, in addition to monitoring the distance between a photolithographic component and a nozzle, the pressure placed on a photolithographic component by a nozzle may also be monitored and controlled. For example, by controlling the flow rate of the chemical, a desired pressure may be applied to the photolithographic component such that a desired distance between the nozzle and the photolithographic component is maintained. In some embodiments, control of the pressure applied on the photolithographic component and distance between the nozzle and the photolithographic component may reduce the risk of pattern collapse and other damage to features on the photolithographic component. As a result, CD uniformity for various pattern densities over the surface of the photolithographic component is improved over that of conventional photolithography methods. Additionally, such methods and systems also allow for development times and etch times less than 100 s, a significant improvement over conventional methods used to reduce microloading effects and CD non-uniformity. In addition, since development times and etch times are relatively short, the volumes of chemicals needed to perform development, etching, layer growth and cleaning steps are significantly reduced. Although the present disclosure and its advantages have been described in detail, it should be understood that various changes, substitutions and alterations can be made herein without departing from the spirit and scope of the disclosure as defined by the following claims.

What is claimed is:

1. A method for performing high flow rate dispensation of a chemical onto a photolithographic component, comprising:
providing a photolithographic component in a manufacturing tool;
positioning the photolithographic component at a predetermined distance from a nozzle operable to dispense a chemical; and
dispensing the chemical on a surface of the photolithographic component at a high flow rate, the rate of flow operable to reduce the occurrence of harmful effects on the surface of the photolithographic component.

2. The method of claim 1, further comprising rotating at least one of:
the photolithographic component at a speed between approximately 1 rpm to approximately 3000 rpm while the chemical is being dispensed; and
the nozzle at a speed between approximately 1 rpm to approximately 3000 rpm while the chemical is being dispensed.

3. The method of claim 1, further comprising providing a distance sensor to determine a distance between the nozzle and the surface of the photolithographic component.

4. The method of claim 1, further comprising providing a pressure sensor to determine a pressure applied by the nozzle onto the photolithographic component.

5. The method of claim 1, wherein the chemical is selected from a group consisting a rinse solution for rinsing the photolithographic component, a developer solution for developing a resist layer disposed on the photolithographic component, a chemical that promotes growth of a layer on the surface of the photolithographic component, and an etching agent for etching the photolithographic component.

6. The method of claim 1, wherein the flow rate is between approximately 0.1 l/min and approximately 10 I/min.

7. The method of claim 1, wherein the photolithographic component is selected from the group consisting of a photomask, a semiconductor wafer, a liquid crystal display, a flat panel display, a digital video disk and a compact disk.

8. The method of claim 1, wherein the predetermined distance comprises a range between approximately 10 microns to approximately 1000 microns.

9. The method of claim 1, further comprising disposing a pad between the nozzle and the photolithographic component, the pad operable to further reduce harmful effects on the surface of the photolithographic component.

10. The method of claim 1, further comprising dispensing the chemical at a substantially uniform temperature.

11. An apparatus for performing high flow rate dispensation of a chemical onto a photolithographic component, comprising:
a nozzle operable to dispense the chemical at a high flow rate on a surface of the photolithographic component, the rate of flow operable to reduce the occurrence of harmful effects across the surface of the photolithographic component; and
a substrate holder operable to position the photolithographic component at a predetermined distance from the nozzle.

12. The apparatus of claim 11, wherein the substrate holder is further operable to rotate the photolithographic component at a speed between approximately 1 rpm to approximately 3000 rpm while the chemical is being dispensed.

13. The apparatus of claim 11, wherein the nozzle is capable of rotating at a speed between approximately 1 rpm to approximately 3000 rpm while the chemical is being dispensed.

14. The apparatus of claim 11, further comprising a distance sensor operable to determine a distance between the nozzle and the surface of the photolithographic component.

15. The apparatus of claim 11, further comprising a pressure sensor operable to determine a pressure applied by the chemical or other solution dispensed by the nozzle onto the surface of the photolithographic component.

16. The apparatus of claim 11, wherein the nozzle is further operable to dispense at least one of:
a rinse solution for rinsing the photolithographic component;
a chemical that promotes growth of a layer on the surface of a photolithographic component; and
an etching agent for etching the photolithographic component.

17. The apparatus of claim 11, wherein the nozzle is further operable to dispense the chemical at a flow rate between approximately 0.1 l/min and approximately 10 l/min.

18. The apparatus of claim 11, wherein the photolithographic component is selected from the group consisting of a photomask, a semiconductor wafer, a liquid crystal display, a flat panel display, a digital video disk and a compact disk.

19. The apparatus of claim 11, wherein the predetermined distance comprises a range between approximately 10 microns to approximately 1000 microns.

20. The apparatus of claim 11, further comprising a pad disposed between the nozzle and the photolithographic component, the pad operable to further reduce harmful effects occurring on the surface of the photolithographic component.

21. The apparatus of claim 11, wherein the chemical comprises a developer solution for developing a resist layer disposed on the photolithographic component.

22. The apparatus of claim 11, wherein the high flow rate ensures uniform development of a pattern across the resist layer.

23. A method for performing high flow rate development of a photolithographic component, comprising:
providing a photolithographic component in a manufacturing tool, the photolithographic component including a resist layer having a pattern imaged therein;
positioning the photolithographic component at a predetermined distance from a nozzle operable to dispense a developer solution; and
dispensing the developer solution on the surface of the resist layer at a high flow rate, the rate of flow operable to ensure uniform development of the pattern across the surface of the photolithographic component.

24. The method of claim 23, further comprising providing a distance sensor to determine a distance between the nozzle and the surface of the resist layer.

25. The method of claim 23, further comprising providing a pressure sensor to determine a pressure applied by the developer solution or other solution dispensed by the nozzle onto the resist layer.

26. The method of claim 23, further comprising dispensing a first rinse solution and a second rinse solution from the nozzle prior to developing the resist layer.

27. The method of claim 23, further comprising developing the resist layer to form the pattern in the resist layer and expose portions of an absorber layer.

28. The method of claim 23, further comprising disposing a pad between the nozzle and the resist layer, the pad operable to further ensure uniform development of the pattern across the surface of the photolithographic component.
